(19) United States
(12) Patent Application Publication
(10) Pub. No.: US 2025/0191984 A1
(43) Pub. Date: Jun. 12, 2025

(54) CERAMIC SUBSTRATE UNIT AND METHOD FOR MANUFACTURING SAME

(71) Applicant: AMOGREENTECH CO., LTD., Gimpo-si, Gyeonggi-do (KR)

(72) Inventor: Jihyung LEE, Gimpo-si (KR)

(73) Assignee: AMOGREENTECH CO., LTD., Gimpo-si, Gyeonggi-do (KR)

(21) Appl. No.: 18/840,791

(22) PCT Filed: Feb. 9, 2023
(86) PCT No.: PCT/KR2023/001906

§ 371 Date: Aug. 22, 2024

(30) Foreign Application Priority Data
Feb. 23, 2022 (KR) 10-2022-0023361

(51) Int. Cl. H01L 23/15; H01L 21/48; H01L 23/00; H01L 23/373; H01L 23/473; H01L 23/498

(52) U.S. Cl. CPC H01L 23/15; H01L 21/4853; H01L 21/4878; H01L 23/3735; H01L 23/473; H01L 23/49811; H01L 23/49866; H01L 24/03; H01L 24/05; H01L 24/29; H01L 24/83; H01L 24/32; H01L 2224/03831; H01L 2224/0384; H01L 2224/05557; H01L 2224/05624; H01L 2224/05647; H01L 2224/29139; H01L 2224/29147; H01L 2224/29166; H01L 2224/32227; H01L 2224/32238; H01L 2224/83203; H01L 2224/8384; H01L 2924/3511; H01L 2924/35121

(57) ABSTRACT

The present invention relates to a ceramic substrate unit and a method for manufacturing same, the ceramic substrate unit comprising: a ceramic substrate comprising a ceramic base material and metal layers provided at the upper and lower surfaces of the ceramic base material; an upper electrode bonded to the upper metal layer of the ceramic substrate, formed to be mounted with a semiconductor chip, and having a first stepped protrusion formed at the outer circumferential surface thereof; and a heat sink bonded to the lower metal layer of the ceramic substrate and having a second stepped protrusion formed at the outer circumferential surface thereof. Accordingly, the present invention can relieve thermal stress.

### TECHNICAL FIELD

The present disclosure relates to a ceramic substrate unit and a method of manufacturing the same, and more specifically, to a ceramic substrate unit capable of easily dispersing stress concentrated on an edge area, and a method of manufacturing the same.

### BACKGROUND ART

In general, electric vehicles require an inverter for converting a direct current voltage provided from a high-voltage battery into an alternating current three-phase voltage to drive a motor.

This inverter is assembled with a power module for adjusting a high voltage of a driving battery to a state suitable for the motor and supplying the adjusted voltage. The power module includes a semiconductor chip for converting conversion, and the semiconductor chip generates high temperature heat due to a high-voltage and high-current operation. When this heat continues, there is a problem in that the semiconductor chip deteriorates, and the performance of the power module deteriorates.

In order to solve this, a heat sink is provided on at least one surface of a ceramic or metal substrate to prevent a deterioration phenomenon of the semiconductor chip due to heat through a heat dissipation function of the heat sink. The heat sink is made of a metal material for heat dissipation, and since the metallic heat sink also has a limitation in heat dissipation, when heat exceeding the limitation is generated, cooling efficiency is degraded rapidly, causing a failure. In addition, there is a problem that the characteristics of the substrate on which semiconductor chips are mounted are degraded due to the occurrence of warpage, etc. caused by heat.

In particular, since an edge area on which stress is concentrated, such as an edge, is vulnerable to a thermal impact, there is a problem that internal cracks and separation easily occur.

### SUMMARY OF INVENTION

### Technical Problem

The present disclosure has been made in efforts to solve the problems and is directed to providing a ceramic substrate unit and a method of manufacturing the same, in which a stair-shaped protrusion may be formed on an outer circumferential surface of each of an upper electrode and a heat sink, thereby relieving thermal stress concentrated on an edge area.

### Solution to Problem

A ceramic substrate unit according to an embodiment of the present disclosure for achieving the object may include a ceramic substrate having a metal layer provided on upper and lower surfaces of a ceramic base, an upper electrode bonded to an upper metal layer of the ceramic substrate, formed so that a semiconductor chip is mounted thereon, and having a first stair-shaped protrusion formed on an outer circumferential surface thereof, and a heat sink bonded to a lower metal layer of the ceramic substrate and having a second stair-shaped protrusion formed on an outer circumferential surface thereof.

Each step forming the stairs in the first protrusion and the second protrusion may have a different protruding length. Here, each step forming the stairs in the first protrusion and the second protrusion may have an increasing protruding length toward the ceramic substrate.

Each step forming the stairs in the first protrusion and the second protrusion may have a side surface with a shape perpendicular to a horizontal line.

Meanwhile, each step forming the stairs in the first protrusion and the second protrusion may include a concave portion, and the concave portion may have a shape that is concave toward the ceramic substrate. Here, the first protrusion and the second protrusion may each have a protrusion end portion formed on a portion on which any one concave portion is in contact with the other concave portion.

The heat sink may include a body portion having an upper surface bonded to the lower metal layer, and a flow path portion disposed on a lower surface of the body portion and forming a passage through which refrigerant flows, and the body portion may have the second protrusion formed on an outer circumferential surface thereof. Here, the plurality of flow path portions may be provided in a bar shape and disposed horizontally at an interval.

The upper electrode and the heat sink may each be made of any one of Cu, Al, and a Cu alloy.

The ceramic substrate unit may further include a first bonding layer disposed between the upper metal layer of the ceramic substrate and the upper electrode and bonding the ceramic substrate and the upper electrode, wherein the first bonding layer may be made of a material including at least one of Ag, Cu, AgCu, and AgCuTi or a material including an Ag sintered body.

The ceramic substrate unit may further include a second bonding layer disposed between the lower metal layer of the ceramic substrate and the heat sink and bonding the ceramic substrate and the heat sink, wherein the second bonding layer may be made of a material including at least one of Ag, Cu, AgCu, and AgCuTi or a material including an Ag sintered body.

A method of manufacturing a ceramic substrate unit according to an embodiment of the present disclosure may include preparing a ceramic substrate including a metal layer provided on upper and lower surfaces of a ceramic base, preparing an upper electrode formed so that a semiconductor chip is mounted thereon and having a first stair-shaped protrusion formed on an outer circumferential surface thereof, preparing a heat sink having a second stair-shaped protrusion formed on an outer circumferential surface thereof, and bonding the upper electrode to an upper metal layer of the ceramic substrate and bonding the heat sink to a lower metal layer of the ceramic substrate.

In the preparing of the upper electrode, the first protrusion may be formed by at least one of chemical etching and cutting machining.

In the preparing the heat sink, the second protrusion may be formed by at least one of chemical etching and cutting machining.

In the preparing the heat sink, the heat sink may include a body portion having an upper surface bonded to the lower metal layer, and a plurality of flow path portions disposed on a lower surface of the body portion and forming a passage through which refrigerant flows, and the body portion may have the second protrusion formed on an outer circumferential surface thereof.

The bonding of the upper electrode to the upper metal layer of the ceramic substrate and bonding of the heat sink to the lower metal layer of the ceramic substrate may include arranging a first bonding layer between the upper metal layer and the upper electrode and arranging a second bonding layer between the lower metal layer and the heat sink, and bonding the upper electrode and the heat sink to the ceramic substrate via the first bonding layer and the second bonding layer, and the first bonding layer and the second bonding layer may be made of a material including at least one of Ag, Cu, AgCu, and AgCuTi or a material including an Ag sintered body.

### Advantageous Effects of Invention

According to the present disclosure, by forming the stair-shaped protrusion on the outer circumferential surface of each of the upper electrode and the heat sink, it is possible to disperse the energy of the edge area, thereby relieving thermal stress, and prevent the upper electrode and the heat sink from being separated from the ceramic substrate, thereby securing reliability.

In addition, according to the present disclosure, since each step forming the stair of the protrusion formed on the outer circumferential surface is formed so that the protruding length increases toward the ceramic substrate, the thickness can decrease toward the edge area, thereby minimizing bonding stress while maintaining bonding strength.

In addition, according to the present disclosure, since the upper electrode is made of any one of Cu, Al, a CuMo alloy, and a CuW alloy and formed in a relatively large thickness, the high voltage and high current can be electrically conducted and the upper electrode can be applied to the high-output power conversion power module by having excellent thermal conductivity.

In addition, according to the present disclosure, since the heat sink is made of any one of Cu, Al, a CuMo alloy, and a CuW alloy and formed in a relatively large thickness, the high heat dissipation conditions required for the power module can be satisfied, and warpage can be suppressed.

In addition, according to the present disclosure, even when high-temperature heat is generated from the semiconductor chip, the heat can be quickly cooled by the heat sink on which the passage through which refrigerant flows is formed, and thus the semiconductor chip can be stably operated without deterioration.

### BRIEF DESCRIPTION OF DRAWINGS

FIG. 1 is a perspective view showing a ceramic substrate unit according to one embodiment of the present disclosure.

FIG. 2 is a cross-sectional view along line A-A′ in FIG. 1.

FIG. 3 is an enlarged cross-sectional view of a protrusion of FIG. 2.

FIG. 4 is an enlarged cross-sectional view of a protrusion in a ceramic substrate unit according to another embodiment of the present disclosure.

FIG. 5 is an enlarged cross-sectional view of the protrusion with three concave portions in the ceramic substrate unit according to another embodiment of the present disclosure.

FIG. 6 is a flowchart showing a method of manufacturing the ceramic substrate unit according to one embodiment of the present disclosure.

### DESCRIPTION OF EMBODIMENTS

Hereinafter, exemplary embodiments according to the present disclosure will be described in detail with reference to the accompanying drawings.

The embodiments are provided to more completely describe the present disclosure to those skilled in the art, and the following embodiments may be modified in various different forms, and the scope of the present disclosure is limited to the following embodiments. Rather, the embodiments are provided to make the disclosure more faithful and complete and fully convey the spirit of the present disclosure.

Terms used herein are intended to describe specific embodiments and are not intended to limit the present disclosure. In addition, in the present specification, singular forms may include plural forms unless the context clearly indicates otherwise.

In the description of the embodiment, when each layer (film), area, pattern, or structure is described as being formed “on” or “under” a substrate, each layer (film), area, pad, or patterns, “on” and “under” include both cases of being formed “directly” or “indirectly with other elements interposed therebetween.” In addition, in principle, the reference for “above” or “under” each layer are based on the drawing.

The drawings are only intended to help understanding of the spirit of the present disclosure and should not be construed as limiting the scope of the present disclosure by the drawings. In addition, in the drawings, a relative thickness and length, or a relative size may be exaggerated for convenience and clarity of description.

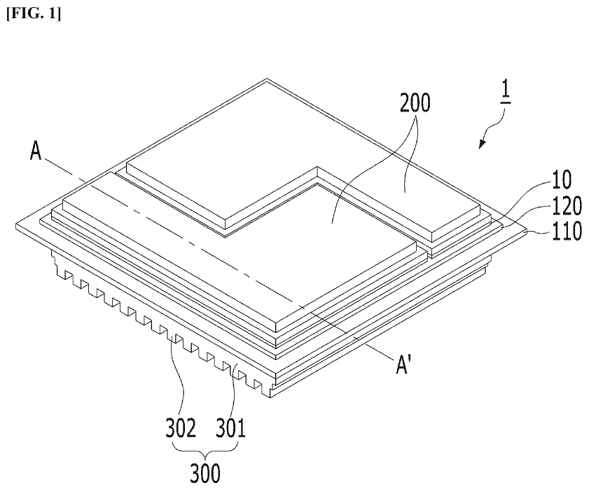

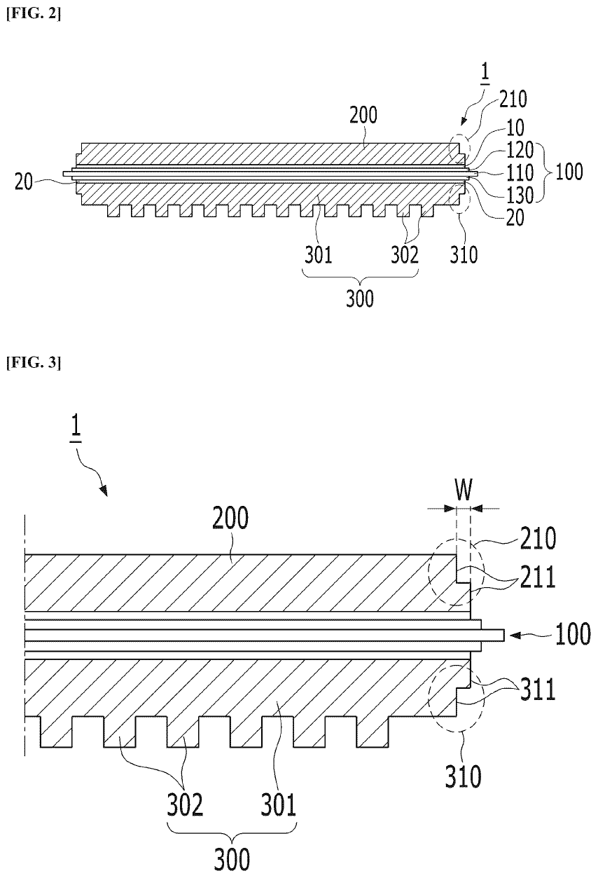

FIG. 1 is a perspective view showing a ceramic substrate unit according to one embodiment of the present disclosure, FIG. 2 is a cross-sectional view along line A-A′ in FIG. 1, and FIG. 3 is an enlarged cross-sectional view of a protrusion of FIG. 2.

As shown in FIGS. 1 to 3, a ceramic substrate unit 1 according to an embodiment of the present disclosure may include a ceramic substrate 100, an upper electrode 200, and a heat sink 300.

The ceramic substrate 100 may be any one of an active metal brazing (AMB) substrate, a direct bonded copper (DBC) substrate, and a thick printing copper (TPC) substrate. These ceramic substrates are substrates in which a metal is directly bonded to a ceramic base. In the embodiment of the present disclosure, the ceramic substrate 100 may include a ceramic base 110, and an upper metal layer 120 and a lower metal layer 130 that are formed on upper and lower surfaces of the ceramic base 110 to increase the heat dissipation efficiency of heat generated from a semiconductor chip (not shown). Here, a thickness of the ceramic base 110 may be 0.32 t, and a thickness of each of the upper and lower metal layers 120 and 130 may be 0.3 t.

The ceramic base 110 may be made of an oxide-based or nitride-based ceramic material. For example, the ceramic base 110 may be any one of alumina (Al₂O₃), AlN, SiN, Si₃N₄, and zirconia toughened alumina (ZTA), but is not limited thereto.

The upper metal layer 120 may be formed on the upper surface of the ceramic base and provided in a shape of a circuit pattern. For example, the upper metal layer 120 may be provided in the form of a metal foil and brazing-bonded to the upper surface of the ceramic base 110 and then formed of an electrode pattern for mounting a semiconductor chip and an electrode pattern for mounting a driving element by etching. For example, the upper metal layer 120 may be made of one of Cu, a Cu alloy (CuMo, etc.), OFC, EPT Cu, and Al. OFC is anoxic copper.

The lower metal layer 130 may be formed on the lower surface of the ceramic base 110 and formed of a flat plate to facilitate heat transfer. The lower metal layer 130 may be provided in the form of a metal foil made of one of Cu, a Cu alloy (CuMo, etc.), OFC, EPT Cu, and Al and brazing-bonded to the lower surface of the ceramic base 110.

The upper electrode 200 may be bonded to the upper metal layer 120 of the ceramic substrate 100 and formed so that the semiconductor chip (not shown) is mounted thereon. The upper electrode 200 may be formed in a shape corresponding to the upper metal layer 120 of the ceramic substrate 100 to have a lower surface bonded to the upper metal layer 120 and formed to have a predetermined thickness.

Specifically, the upper electrode 200 may be formed to have a thickness ranging from 0.6 mm or more to 9.0 mm or less. As described above, when the upper electrode 200 is formed thick, a high voltage and high current may be electrically conducted. Since railway vehicles perform high-output power conversion compared to general vehicles, the upper electrode 200 should have high electrical conductivity and high thermal conductivity for heat dissipation. In the ceramic substrate unit 1 according to the embodiment of the present disclosure, since the upper electrode 200 is made of any one of Cu, Al, a CuMo alloy, and a CuW alloy and formed in a relatively large thickness ranging from 0.6 mm or more to 9.0 mm or less, there is an advantage of being applicable to high-output power conversion power modules by having excellent electrical and thermal conductivity.

In addition, the upper electrode 200 may have a first stair-shaped protrusion 210 formed on the outer circumferential surface thereof. Here, the stair shape means a shape of multiple steps. Since an edge area on which stress is concentrated, such as an edge, is vulnerable to a thermal impact, there is a problem that internal cracks and separation easily occur. Due to such a stress concentration phenomenon near the edge, there is a problem that the upper electrode 200 is separated from the upper metal layer 120 of the ceramic substrate 100 in a sudden change in temperature. To prevent this, according to the present disclosure, by forming the first stair-shaped protrusion 210 on the outer circumferential surface of the upper electrode 200, it is possible to minimize the thickness of the edge area, thereby dispersing the energy of the edge area and relieving thermal stress.

The first protrusion 210 may be formed in a shape having a plurality of steps, and each step may be formed to have a width w ranging from 0.35 mm to 1.2 mm. A side surface 211 of each step in the first protrusion 210 may have a shape that is perpendicular to a horizontal line. Although not shown, the side surface 211 of each step in the first protrusion 210 may have a shape that forms an acute or obtuse angle with respect to the horizontal line. In addition, each step forming the stair in the first protrusion 210 may be formed to have a different protruding length. Specifically, each step forming the stair in the first protrusion 210 may be formed to have an increasing protruding length toward the ceramic substrate 100, and thus may have a decreasing thickness toward the edge area, thereby minimizing bonding stress while maintaining bonding strength.

The semiconductor chip mounted on the upper electrode 200 may be a semiconductor chip such as SiC, GaN, Si, an LED, or a VCSEL. The semiconductor chip may be bonded to an upper surface of the upper electrode 200 by a bonding layer (not shown) containing solder or Ag paste. In this case, at least two semiconductor chips may be bonded to the upper electrode 200, and the semiconductor chips may be electrically connected by wire bonding, flip-chip bonding, etc.

The upper electrode 200 may be bonded to the upper metal layer 120 of the ceramic substrate 100 via a first bonding layer 10. In this case, the first bonding layer 10 may be a brazing bonding layer or an Ag sintering bonding layer made of a material including at least one of Ag, Cu, AgCu, and AgCuTi. When the first bonding layer 10 is a brazing bonding layer, the brazing bonding layer may be disposed between the upper metal layer 120 of the ceramic substrate 100 and the upper electrode 200 and may integrally bond the ceramic substrate 100 and the upper electrode 200 at a brazing temperature. The brazing temperature may be 450° C. or higher. Ag, AgCu, and AgCuTi may serve to increase bonding strength due to high thermal conductivity and at the same time, facilitate heat transfer between the ceramic substrate 100 and the upper electrode 200, thereby increasing heat dissipation efficiency.

When the first bonding layer 10 is an Ag sintered bonding layer, the first bonding layer 10 may be made of a material including an Ag sintered body. For example, when the first bonding layer 10 is an Ag sintered body film, the Ag sintered body film may be disposed between the upper metal layer 120 of the ceramic substrate 100 and the upper electrode 200, and in this state, by applying a pressure to the above assembly and hardening the same, the ceramic substrate 100 and the upper electrode 200 may be integrally bonded. As described above, a method of hardening the Ag sintered body film enables bonding at a relatively low pressure and low temperature, has high high-temperature stability, and has excellent bonding strength of about 80 MPa. As described above, the ceramic substrate 100 and the upper electrode 200 are airtightly bonded by a bonding method such as brazing bonding or Ag sintering bonding, thereby having high bonding strength and excellent high-temperature reliability. The ceramic substrate 100 and the upper electrode 200 may be temporarily bonded by thermochemical bonding and then brazing-bonded or Ag sintering-bonded. In this case, the thermochemical bonding may be bonding using heat fusion, an adhesive, a gluing agent, etc.

The heat sink 300 may be bonded to the lower metal layer 130 of the ceramic substrate 100 and made of any one of Cu, Al, a CuMo alloy, and a CuW alloy to increase heat dissipation efficiency. As an example, the heat sink 300 may be made of at least one of Cu, Al, AlSiC, CuMo, CuW, Cu/CuMo/Cu, Cu/Mo/Cu, and Cu/W/Cu, or a composite material thereof. Here, the materials of Cu, Al, AlSiC, CuMo, CuW, Cu/CuMo/Cu, Cu/Mo/Cu, and Cu/W/Cu may have excellent thermal conductivity, and the materials of AlSiC, CuMo, CuW, Cu/CuMo/Cu, Cu/Mo/Cu, and Cu/W/Cu may have low thermal expansion coefficients, thereby minimizing the occurrence of warpage when bonded to the ceramic substrate 100.

The heat sink 300 may be formed to have a thickness ranging from 0.6 mm or more and 9.0 mm or less. The heat sink 300 may made of any one of Cu, Al, a CuMo alloy, and a CuW alloy, thereby having excellent thermal conductivity, and may be formed in a relatively large thickness ranging from 0.6 mm or more and 9.0 mm or less corresponding to the upper electrode 200, thereby suppressing warpage and also improving heat dissipation performance due to widely spread heat dissipation. Therefore, even when high-temperature heat is generated from the semiconductor chip, heat can be effectively dissipated by the heat sink 300, and thus the semiconductor chip can operate stably without deterioration.

The heat sink 300 may be operated by any one of an air-cooled method or a water-cooled method. Here, for the air-cooled method, air may be supplied as refrigerant, and for the water-cooled method, cooling water, liquid nitrogen, alcohol, or other solvents may be supplied by being circulated as refrigerant by a pumping force. For example, for the water-cooled heat sink 300, heat may be quickly absorbed and discharged as a flow rate of the refrigerant is adjusted and forcibly cooled by the continuously circulating refrigerant, thereby preventing overheating of the semiconductor chip.

The heat sink 300 may be any one of micro channel, pin fin, micro jet, and slit types, and in the present embodiment, a slit type heat sink 300 in which a plurality of bar-shaped flow path portions 302 are horizontally disposed at intervals will be described.

The heat sink 300 may include a body portion 301 whose upper surface is bonded to the lower metal layer 130 of the ceramic substrate 100, and a flow path portion 302 disposed on a lower surface of the body portion 301. The body portion 301 may be provided in the form of a flat plate so that the upper surface may be in direct contact with the lower metal layer 130 and bonding strength and heat dissipation performance can be increased to maximally increase a bonding area with the lower metal layer 130. A plurality of flow path portions 302 may be disposed on the lower surface of the body portion 301 at an interval and may form a passage through which the refrigerant flows. Although not shown, the flow path portion 302 may be provided in various pin shapes such as a cylinder, a polygonal column, a teardrop shape, and a diamond shape. The shape of the flow path portion 302 may be implemented by mold processing, etching processing, milling processing, and other processing.

Here, a thickness of the body portion 301 may be formed to be larger than a thickness of the flow path portion 302. As an example, when the thickness of the body portion 301 is 2.0 mm, the thickness of the flow path portion 302 may be 1.0 mm. Since the body portion 301 is a portion that is in contact with the lower metal layer 130 of the ceramic substrate 100 and directly transfers heat, when the body portion 301 is formed to be larger than the thickness of the flow path portion 302, the heat spreads widely, thereby making it easy to suppress warpage at a high temperature and improving heat dissipation performance.

The heat sink 300 may have a second stair-shaped protrusion 310 formed on the outer circumferential surface thereof. Specifically, the heat sink 300 may have the second stair-shaped protrusion 310 formed on the outer circumferential surface of the body portion 301. Here, the stair shape means a shape of multiple steps. Since an edge area on which stress is concentrated, such as an edge, is vulnerable to a thermal impact, there is a problem that internal cracks and separation easily occur. Due to such a stress concentration phenomenon near the edge, there is a problem that the heat sink 300 is separated from the lower metal layer 130 of the ceramic substrate 100 in a sudden change in temperature. To prevent this, according to the present disclosure, by forming the second stair-shaped protrusion 310 on the outer circumferential surface of the heat sink 300, it is possible to minimize the thickness of the edge area, thereby dispersing the energy of the edge area and relieving thermal stress.

The second protrusion 310 may be formed in a shape having a plurality of steps, and each step may be formed to have a width w ranging from 0.35 mm to 1.2 mm. A side surface 311 of each step in the second protrusion 310 may have a shape that is perpendicular to a horizontal line. Although not shown, the side surface 311 of each step in the second protrusion 310 may have a shape that forms an acute or obtuse angle with respect to the horizontal line. In addition, each step forming the stair in the second protrusion 310 may be formed to have a different protruding length. Specifically, each step forming the stair in the second protrusion 310 may be formed to have an increasing protruding length toward the ceramic substrate 100, and thus may have a decreasing thickness toward the edge area, thereby minimizing bonding stress while maintaining bonding strength.

The heat sink 300 may be bonded to the lower metal layer 130 of the ceramic substrate 100 via the second bonding layer 20. In this case, the second bonding layer 20 may be a brazing bonding layer or an Ag sintering bonding layer made of a material including at least one of Ag, Cu, AgCu, and AgCuTi. When the second bonding layer 20 is a brazing bonding layer, the brazing bonding layer may be disposed between the lower metal layer 130 of the ceramic substrate 100 and the heat sink 300 and may integrally bond the ceramic substrate 100 and the heat sink 300 at a brazing temperature. The brazing temperature may be 450° C. or higher. Ag, AgCu, and AgCuTi may serve to increase bonding strength due to high thermal conductivity and at the same time, facilitate heat transfer between the ceramic substrate 100 and the heat sink 300, thereby increasing heat dissipation efficiency.

When the second bonding layer 20 is an Ag sintered bonding layer, the second bonding layer 20 may be made of a material including an Ag sintered body. For example, when the second bonding layer 20 is an Ag sintered body film, the Ag sintered body film may be disposed between the lower metal layer 130 of the ceramic substrate 100 and the heat sink 300, and in this state, by applying a pressure to the above assembly and hardening the same, the ceramic substrate 100 and the heat sink 300 may be integrally bonded. As described above, a method of hardening the Ag sintered body film enables bonding at a relatively low pressure and low temperature, has high high-temperature stability, and has excellent bonding strength of about 80 MPa. As described above, the ceramic substrate 100 and the heat sink 300 may be airtightly bonded by the bonding method such as the brazing bonding or the Ag sintering bonding, may have a high bonding strength capable of withstanding a water pressure, a hydraulic pressure, etc., and have excellent high-temperature reliability. The ceramic substrate 100 and the heat sink 300 may be temporarily bonded by thermochemical bonding and then brazing-bonded or Ag sintering-bonded. In this case, the thermochemical bonding may be bonding using heat fusion, an adhesive, a gluing agent, etc.

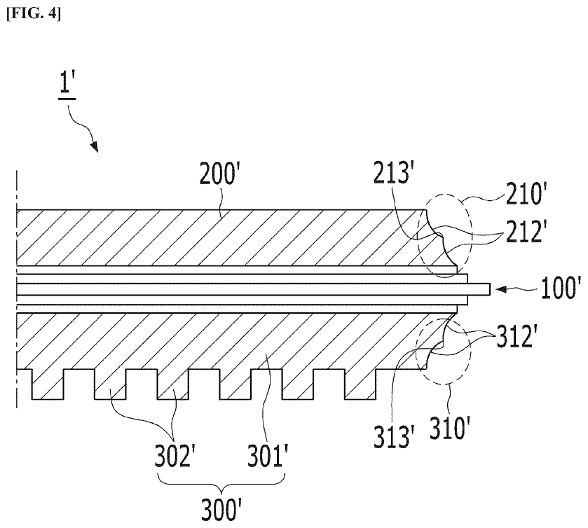

FIG. 4 is an enlarged cross-sectional view of a protrusion in a ceramic substrate unit according to another embodiment of the present disclosure.

As shown in FIG. 4, a ceramic substrate unit 1′ according to another embodiment of the present disclosure may be formed so that each step forming a stair in a first protrusion 210′ of an upper electrode 200′ includes a first concave portion 212′ and each step forming a stair in a second protrusion 310′ of a heat sink 300′ includes a second concave portion 312′. The first and second concave portions 212′ and 312′ may have a curved inclination and may be formed in a concave shape toward the ceramic substrate 100.

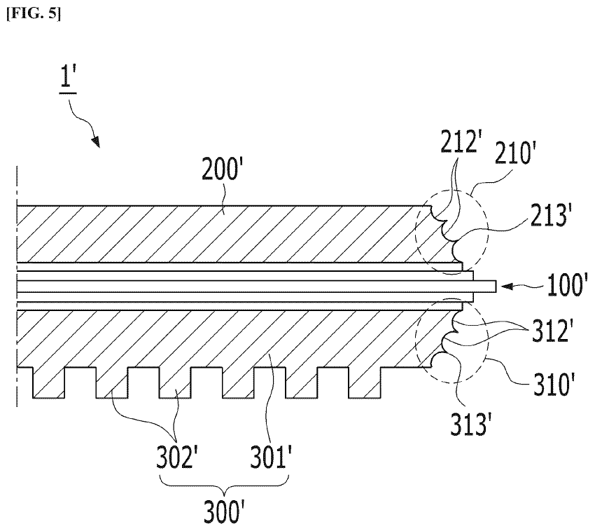

The upper electrode 200′ and the heat sink 300′ may be formed with the protrusions 210′ and 310′ including two concave portions 212′ and 312′, respectively. In addition, as shown in FIG. 5, the upper electrode 200′ and the heat sink 300′ may be formed with the protrusions 210′ and 310′ including three concave portions 212′ and 312′, respectively, and the number of concave portions 212′ and 312′ is not limited thereto.

The first protrusion 210′ may have a first pointed protrusion end portion 213′ formed on a portion on which any one first concave portion 212′ is in contact with the other concave portion 212′. The second protrusion 310′ may have a second pointed protrusion end portion 312′ on a portion on which any one second concave portion 312′ is in contact with the other concave portion 312′. As described above, the first and second concave portions 212′ and 312′ may have a curved inclination and may be formed in a concave shape toward the ceramic substrate 100, thereby relieving the stress concentration phenomenon near the edge.

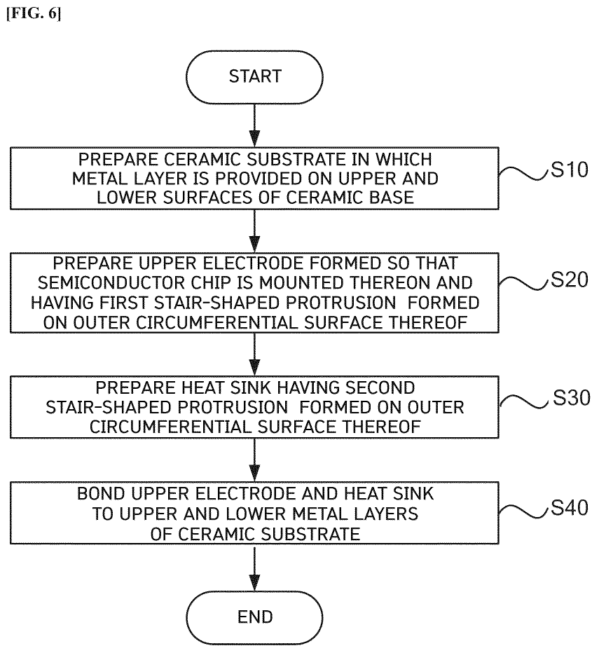

FIG. 6 is a flowchart showing a method of manufacturing the ceramic substrate unit according to one embodiment of the present disclosure.

As shown in FIG. 6, a method of manufacturing the ceramic substrate unit according to one embodiment of the present disclosure may include preparing the ceramic substrate 100 having the metal layers 120 and 130 provided on the upper and lower surfaces of the ceramic base 110 (S10), preparing the upper electrode 200 formed so that a semiconductor chip is mounted thereon and having the stair-shaped protrusion 210 formed on the outer circumferential surface thereof (S20), preparing the heat sink 300 having the stair-shaped protrusion 310 formed on the outer circumferential surface thereof (S30), and bonding the upper electrode 200 to the upper metal layer of the ceramic substrate 100 and bonding the heat sink 300 to the lower metal layer 130 of the ceramic substrate 100 (S40). Here, each operation may be performed sequentially or performed in a reversed order, and performed substantially at the same time. In the present embodiment, the first protrusion 210 and the second protrusion 310 are formed before the bonding (S40), but the first protrusion 210 and the second protrusion 310 may be formed by machining the outer circumferential surface of each of the upper electrode 200 and the heat sink 300 after the bonding (S40).

In the preparing of the ceramic substrate 100 (S10), the ceramic substrate 100 may be any one of an AMB substrate, a DBC substrate, and a TPC substrate in which the metal layers 120 and 130 are provided on the upper and lower surfaces of the ceramic base 110.

In the preparing of the upper electrode 200 (S20), the upper electrode 200 may be formed so that the semiconductor chip is mounted thereon and formed in a shape corresponding to the upper metal layer 120 of the ceramic substrate 100. Since the upper electrode 200 is made of any one of Cu, Al, a CuMo alloy, and a CuW alloy and formed in a relatively large thickness ranging from 0.6 mm or more to 9.0 mm or less, the upper electrode 200 can be applied to high-output power conversion power modules by having excellent electrical conductivity and thermal conductivity.

In the preparing of the upper electrode 200 (S20), the upper electrode 200 may be formed so that the semiconductor chip is mounted thereon and may have the first stair-shaped protrusion 210 formed on the outer circumferential surface thereof. As described above, when the second stair-shaped protrusion 310 is formed on the edge area such as the outer circumferential surface of the upper electrode 200, it is possible to easily disperse stress concentrated on the edge area in a sudden change in temperature, thereby relieving thermal stress.

In the preparing of the upper electrode 200 (S20), the first protrusion 210 may be formed by at least one of chemical etching and cutting machining. Although not shown, in the case of the chemical etching, the first protrusion 210 may be formed by forming at least one mask (not shown) on one surface of the upper electrode 200 and then selectively etching the upper electrode 200 exposed by the mask. In addition, the cutting machining may form the first protrusion 210 by machining the upper electrode 200 in a manner of mechanical milling machining, etc. In addition, the first protrusion 210 may be formed by cutting a portion of the upper electrode 200 by the cutting machining and then finely etching the same by the chemical etching.

In the preparing of the heat sink 300 (S30), the heat sink 300 may be formed with the second stair-shaped protrusion 310 on the outer circumferential surface thereof. As described above, when the second stair-shaped protrusion 310 is formed on the edge area such as the outer circumferential surface of the heat sink 300, it is possible to easily disperse stress concentrated on the edge area in a sudden change in temperature, thereby relieving thermal stress.

In the preparing of the heat sink 300 (S30), the second protrusion 310 may be formed by at least one of chemical etching and cutting machining. Although not shown, in the case of the chemical etching, the second protrusion 310 may be formed by forming at least one mask (not shown) on one surface of the heat sink 300 and then selectively etching the heat sink 300 exposed by the mask. In addition, the cutting machining may form the second protrusion 310 by machining the heat sink 300 in a manner of mechanical milling machining, etc. In addition, the second protrusion 310 may be formed by cutting a portion of the heat sink 300 by the cutting machining and then finely etching the same by the chemical etching.

In the preparing of the heat sink 300 (S30), the heat sink 300 may be formed to have a thickness ranging from 0.6 mm or more to 9.0 mm or less. The heat sink 300 may made of any one of Cu, Al, a CuMo alloy, and a CuW alloy, thereby having excellent thermal conductivity, and may be formed in a relatively large thickness ranging from 0.6 mm or more and 9.0 mm or less corresponding to the upper electrode 200, thereby suppressing warpage and also improving heat dissipation performance due to widely spread heat dissipation.

In the preparing of the heat sink 300 (S30), the heat sink 300 may include the body portion 301 and the flow path portion 302. The body portion 301 is a portion whose upper surface is bonded to the lower metal layer 130 and may be provided in the form of a flat plate to maximally increase the bonding area. Here, the body portion 301 may have the second protrusion 310 formed on the outer circumferential surface thereof. A plurality of flow path portions 302 may be disposed on the lower surface of the body portion 301 at an interval and may form a passage through which the refrigerant flows. The shape of the flow path portion 302 may be implemented by mold processing, etching processing, milling processing, and other processing. In addition, a thickness of the body portion 301 may be formed to be larger than a thickness of the flow path portion 302. As an example, when the thickness of the body portion 301 is 2.0 mm, the thickness of the flow path portion 302 may be 1.0 mm.

The bonding of the upper electrode 200 to the upper metal layer 120 of the ceramic substrate 100 and bonding of the heat sink 300 to the lower metal layer 130 of the ceramic substrate 100 (S40) may include arranging the first bonding layer 10 between the upper metal layer 120 of the ceramic substrate and the upper electrode 200 and arranging the second bonding layer 20 between the lower metal layer 130 of the ceramic substrate 100 and the heat sink 300, and bonding the upper electrode 200 and the heat sink 300 on the ceramic substrate 100 via the first bonding layer 10 and the second bonding layer 20.

Here, the first and second bonding layers 10 and 20 are made of a material including at least one of Ag, Cu, AgCu, and AgCuTi or a material including an Ag sintered body. When the first and second bonding layers 10 and 20 are brazing bonding layers made of the material including at least one of Ag, Cu, AgCu, and AgCuTi, the brazing bonding layer may be disposed between the lower metal layer 130 of the ceramic substrate 100 and the heat sink 300 and may integrally bond the ceramic substrate 100 and the heat sink 300. The first and second bonding layers 10 and 20 may be formed by any one method of plating, paste application, and foil attachment and may have a thickness ranging from about 0.3 to 3.0 μm. The brazing bonding may be performed at 450° C. or higher, preferably, in a range of 780 to 900° C., and pressing by a jig may be performed during brazing to increase bonding strength.

When the first and second bonding layers 10 and 20 are Ag sintered bonding layers, the first and second bonding layers 10 and 20 may be made of a material including an Ag sintered body. For example, when the second bonding layer 20 is an Ag sintered body film, the Ag sintered body film may be disposed between the upper metal layer 120 and the upper electrode 200 and between the lower metal layer 130 and the heat sink 300, and in this state, by applying a pressure to the above assembly and hardening the same, the upper electrode 200 and the heat sink 300 may be integrally bonded to the ceramic substrate 100. As described above, a method of hardening the Ag sintered body film enables bonding at a relatively low pressure and low temperature, has high high-temperature stability, and has excellent bonding strength of about 80 MPa.

In the above-described ceramic substrate unit according to the present disclosure, by forming the stair-shaped protrusion on the outer circumferential surface of each of the upper electrode and the heat sink, it is possible to disperse the energy of the edge area, thereby relieving thermal stress, and prevent the upper electrode and the heat sink from being separated from the ceramic substrate, thereby securing reliability.

In addition, since the ceramic substrate unit according to the present disclosure has a structure in which the upper electrode 200 and the heat sink 300, which have a thickness ranging from 0.6 mm or more to 9.0 mm or less, are bonded to the upper and lower metal layers 120 and 130 of the ceramic substrate 100, respectively, the ceramic substrate unit can be used for high-output power conversion or applied to a device requiring the guarantee of the thermal characteristics, etc.

In addition, since the ceramic substrate unit according to the present disclosure has the upper electrode 200 and the heat sink 300 brazing-bonded or Ag sintering-bonded to the upper and lower metal layers 120 and 130 of the ceramic substrate 100, respectively, the ceramic substrate unit may have solid bonding strength and excellent thermal conductivity, thereby satisfying high heat dissipation conditions required for power modules.

The above-described ceramic substrate unit according to the present disclosure can be applied to various devices requiring high power and high heat dissipation characteristics in addition to single-sided or double-sided cooling power modules.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but intended to describe the same, and the scope of the technical spirit of the present disclosure is not limited by these embodiments. The scope of the present disclosure should be construed by the appended claims, and all technical spirits within the equivalent scope should be construed as being included in the scope of the present disclosure.

1. A ceramic substrate unit comprising:
a ceramic substrate having a metal layer provided on upper and lower surfaces of a ceramic base;
an upper electrode bonded to an upper metal layer of the ceramic substrate, formed so that a semiconductor chip is mounted thereon, and having a first stair-shaped protrusion formed on an outer circumferential surface thereof; and
a heat sink bonded to a lower metal layer of the ceramic substrate and having a second stair-shaped protrusion formed on an outer circumferential surface thereof.

2. The ceramic substrate unit of claim 1, wherein each step forming the stairs in the first protrusion and the second protrusion has a different protruding length.

3. The ceramic substrate unit of claim 1, wherein each step forming the stairs in the first protrusion and the second protrusion has an increasing protruding length toward the ceramic substrate.

4. The ceramic substrate unit of claim 1, wherein each step forming the stairs in the first protrusion and the second protrusion has a side surface with a shape perpendicular to a horizontal line.

5. The ceramic substrate unit of claim 1, wherein each step forming the stairs in the first protrusion and the second protrusion includes a concave portion, and
the concave portion has a shape that is concave toward the ceramic substrate.

6. The ceramic substrate unit of claim 5, wherein the first protrusion and the second protrusion each have a protrusion end portion formed on a portion on which any one concave portion is in contact with the other concave portion.

7. The ceramic substrate unit of claim 1, wherein the heat sink includes:
a body portion having an upper surface bonded to the lower metal layer; and
a flow path portion disposed on a lower surface of the body portion and forming a passage through which refrigerant flows, and
the body portion has the second protrusion formed on an outer circumferential surface thereof.

8. The ceramic substrate unit of claim 7, wherein the plurality of flow path portions are provided in a bar shape and disposed horizontally at an interval.

9. The ceramic substrate unit of claim 1, wherein the upper electrode and the heat sink are each made of any one of Cu, Al, and a Cu alloy.

10. The ceramic substrate unit of claim 1, further comprising a first bonding layer disposed between the upper metal layer of the ceramic substrate and the upper electrode and bonding the ceramic substrate and the upper electrode,
wherein the first bonding layer is made of a material including at least one of Ag, Cu, AgCu, and AgCuTi or a material including an Ag sintered body.

11. The ceramic substrate unit of claim 1, further comprising a second bonding layer disposed between the lower metal layer of the ceramic substrate and the heat sink and bonding the ceramic substrate and the heat sink,
wherein the second bonding layer is made of a material including at least one of Ag, Cu, AgCu, and AgCuTi or a material including an Ag sintered body.

12. A method of manufacturing a ceramic substrate unit, comprising:
preparing a ceramic substrate including a metal layer provided on upper and lower surfaces of a ceramic base;
preparing an upper electrode formed so that a semiconductor chip is mounted thereon and having a first stair-shaped protrusion formed on an outer circumferential surface thereof;
preparing a heat sink having a second stair-shaped protrusion formed on an outer circumferential surface thereof; and
bonding the upper electrode to an upper metal layer of the ceramic substrate and bonding the heat sink to a lower metal layer of the ceramic substrate.

13. The method of claim 12, wherein in the preparing of the upper electrode,
the first protrusion is formed by at least one of chemical etching and cutting machining.

14. The method of claim 12, wherein in the preparing the heat sink,
the second protrusion is formed by at least one of chemical etching and cutting machining.

15. The method of claim 12, wherein in the preparing the heat sink,
the heat sink includes:
a body portion having an upper surface bonded to the lower metal layer; and
a plurality of flow path portions disposed on a lower surface of the body portion and forming a passage through which refrigerant flows, and
the body portion has the second protrusion formed on an outer circumferential surface thereof.

16. The method of claim 12, wherein the bonding of the upper electrode to the upper metal layer of the ceramic substrate and bonding of the heat sink to the lower metal layer of the ceramic substrate includes:
arranging a first bonding layer between the upper metal layer and the upper electrode and arranging a second bonding layer between the lower metal layer and the heat sink; and
bonding the upper electrode and the heat sink to the ceramic substrate via the first bonding layer and the second bonding layer, and
the first bonding layer and the second bonding layer are made of a material including at least one of Ag, Cu, AgCu, and AgCuTi or a material including an Ag sintered body.
